(19) United States
(12) Patent Application Publication
(10) Pub. No.: US 2023/0418992 A1
(43) Pub. Date: Dec. 28, 2023

(54) CONTEXT AWARE OPTIMIZED DIGITAL TWIN MODEL CREATION

(71) Applicant: International Business Machines Corporation, Armonk, NY (US)

(72) Inventors: Shailendra Moyal, Pune (IN); Akash U. Dhoot, Pune (IN); Nitika Sharma, Pune (IN); Sarbajit K. Rakshit, Pune (IN)

(21) Appl. No.: 17/809,066

(22) Filed: Jun. 27, 2022

(51) Int. Cl. G06F 30/20

(52) U.S. Cl. CPC G06F 30/20

(57) ABSTRACT

In an approach for building a subset of a digital twin model, a processor monitors a digital twin model of a machine for one or more changes to the machine. Responsive to detecting a change to the machine, a processor analyzes one or more aspects of the machine, wherein the one or more aspects of the machine include a contextual situation of the machine and one or more activities performed by the machine. Responsive to determining the contextual situation of the machine has changed, a processor analyzes one or more sensors and a first set of data generated by the one or more sensors. A processor determines the one or more sensors are generating a required type of data and a required amount of data to create a subset of the digital twin model. A processor creates the subset of the digital twin model incorporating the change detected.

### BACKGROUND OF THE INVENTION

The present invention relates generally to the field of digital twins, and more particularly to context aware optimized digital twin model creation using appropriate influencing factors.

A digital twin is a virtual representation of a physical object, system, or other asset (hereinafter referred to as a “physical asset”) across its life-cycle. The digital twin integrates Internet of Things (IoT), Artificial Intelligence (AI), machine learning, and software analytics with spatial network graphs to create a complex virtual model that is an exact counterpart to the physical asset existing in real space. The digital twin tracks changes to the physical asset across the physical asset's life-cycle and records the changes as they occur. Sensors and IoT devices connected to the physical asset collect data, often in real-time. The collected data can then be mapped to the virtual model of the digital twin. Any individual with access to the digital twin can see real-time information about the physical asset while the physical asset is operating in the real world without having to be physically present. The individual with access to the digital twin can use the digital twin to understand not only how the physical asset is performing, but to also predict how the physical asset may perform in the future, using the data collected from sensors, IoT devices, and other sources of data and information being collected.

The digital twin finds an application in many fields but mainly in product lifecycle management, advanced manufacturing, project planning, reliability engineering, training, real-time decision making, and decommissioning resources. For example, the digital twin can ensure that the requirements captured during the earliest stages of a physical asset's lifecycle are verified, maintained, and completed as the physical asset is built, enters service, evolves during service, and is ultimately retired, decommissioned, and recycled. In another example, the digital twin can compare different lifecycle plans based on an impact from other digital twins as the digital twins evolve to assist with contingency and resilience management to ensure a plan is achievable. In yet another example, the digital twin can monitor performance of a physical asset in as near to real-time as is needed and can digitally reflect sensor information from the real-world instance of the physical asset so that engineers can improve overall performance, increase system efficiency, and optimize behavior.

### SUMMARY

Aspects of an embodiment of the present invention disclose a method, computer program product, and computer system for building a subset of digital twin models based on a contextual need to perform a simulation for a derived activity surrounding and relative data gathered from various sensors placed within that surrounding. A processor monitors a digital twin model of a machine for one or more changes to the machine. Responsive to detecting a change to the machine, a processor analyzes one or more aspects of the machine, wherein the one or more aspects of the machine include a contextual situation of the machine and one or more activities performed by the machine in the contextual situation. Responsive to determining the contextual situation of the machine has changed, a processor analyzes one or more sensors associated with the machine and a first set of data generated by the one or more sensors associated with the machine. A processor determines the one or more sensors associated with the machine are generating a required type of data and a required amount of data to create a subset of the digital twin model of the machine. A processor creates the subset of the digital twin model of the machine incorporating the change detected.

In some aspects of an embodiment of the present invention, prior to monitoring the digital twin model of the machine for the one or more changes to the machine, a processor receives a request to create the digital twin model of the machine. A processor gathers a second set of data about the machine. A processor creates the digital twin model of the machine.

In some aspects of an embodiment of the present invention, a processor analyzes the second set of data to evaluate an adaptability of the machine. A processor analyzes the second set of data to predict the contextual situation of the machine. A processor analyzes the second set of data to predict the one or more activities performed by the machine in the contextual situation. A processor analyzes the second set of data to predict a type of data generated by the one or more sensors associated with the machine. A processor analyzes the second set of data to predict a volume of the type of data predicted to be generated by the one or more sensors associated with the machine.

In some aspects of an embodiment of the present invention, a processor stores the second set of data about the machine in a knowledge corpus.

In some aspects of an embodiment of the present invention, a processor determines whether the type of data generated by the one or more sensors associated with the machine has changed. A processor determines whether a priority level of the type of data generated by the one or more sensors associated with the machine has changed.

In some aspects of an embodiment of the present invention, a processor determines the one or more sensors associated with the machine are not generating the required type of data to create the subset of the digital twin model of the machine based on the digital twin. A processor recommends one or more additional sensors be installed in the contextual situation of the machine. A processor proactively installs one or more additional sensors in the contextual situation of the machine.

In some aspects of an embodiment of the present invention, a processor determines the one or more sensors associated with the machine are not generating the required amount of data to create the subset of the digital twin model of the machine based on the digital twin. A processor enables an external scanning component to generate the required amount of data to create the subset of the digital twin model of the machine.

These and other features and advantages of the present invention will be described in, or will become apparent to those of ordinary skill in the art in view of, the following detailed description of the example embodiments of the present invention.

### BRIEF DESCRIPTION OF THE DRAWINGS

FIG. 1 is a block diagram illustrating a distributed data processing environment, in accordance with an embodiment of the present invention;

FIG. 2 is a block diagram illustrating the components of a server within the distributed data processing environment of FIG. 1, in accordance with an embodiment of the present invention;

FIG. 3 is a block diagram illustrating an exemplary cloud computing environment, in accordance with an embodiment of the present invention;

FIG. 4 is a block diagram illustrating a set of functional abstraction model layers of the exemplary cloud computing environment, in accordance with an embodiment of the present invention;

FIG. 5 is a flowchart illustrating the operational steps of a setup component of an optimized digital twin creation program, on the server within the distributed data processing environment of FIG. 1, in accordance with an embodiment of the present invention; and

FIG. 6 is a flowchart illustrating the operational steps of the optimized digital twin creation program, on the server within the distributed data processing environment of FIG. 1, in accordance with an embodiment of the present invention.

### DETAILED DESCRIPTION

Embodiments of the present invention recognize that a digital twin is a virtual representation of a physical object, system, or other asset (hereinafter referred to as a “physical asset”) across its life-cycle.

Embodiments of the present invention recognize that a physical asset may perform a plurality of activities in a plurality of working surroundings (i.e., contextual situations). For example, a vehicle may be used for commuting from one point to another. The vehicle may also be used for transporting goods. The vehicle may be performing one of a plurality of activities in good weather or in bad weather and may be performing one of a plurality of activities on a good road or on a bad road. Therefore, the vehicle may be controlled in different manners depending on the contextual situation in which the car is found.

Embodiments of the present invention recognize that, when creating a digital twin model of a machine or device, all possible sensor feeds are used. A machine is an apparatus using or applying mechanical power and having several parts, each with a definite function and together performing a particular task. In addition to an apparatus, a machine may be, but is not limited to, a physical asset, an appliance, an instrument, a tool, a device, a unit, a contraption, a gadget, a mechanism, an engine, a motor, a lever, or a pulley. Embodiments of the present invention, however, recognize that all possible sensor feeds are not necessary in every contextual situation. Rather, each contextual situation requires a different set of sensor feeds. A working surrounding or a contextual situation includes the circumstances, conditions, or objects by which the machine is surrounded. Embodiments of the present invention recognize that, if all possible sensor feeds are used when creating a digital twin model of a machine or device, then an increase in the volume of data will occur and will require additional processing capabilities and time. Therefore, embodiments of the present invention recognize the need for a system and method to optimize the creation of a digital twin model using an appropriate set of internal and external influencing factors.

Embodiments of the present invention provide a system and method to build a subset of digital twin models based on a contextual need to perform a simulation for a derived activity surrounding and relative data gathered from various sensors placed within that surrounding.

Implementation of embodiments of the present invention may take a variety of forms, and exemplary implementation details are discussed subsequently with reference to the Figures.

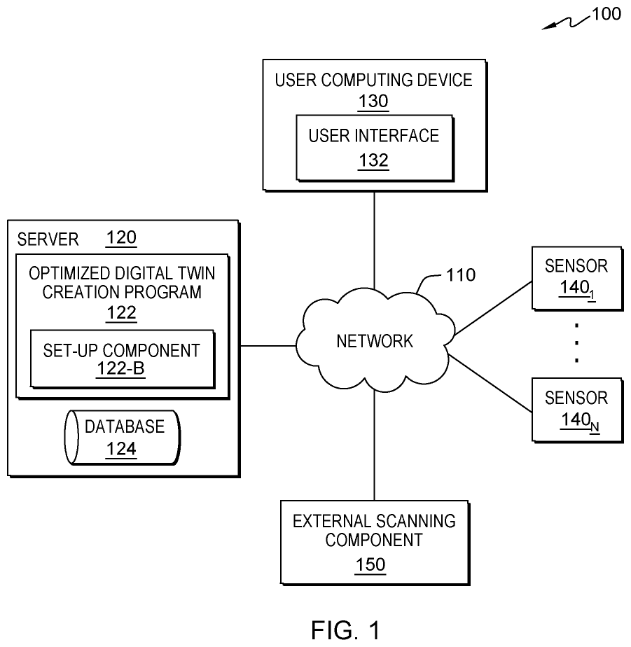

FIG. 1 is a block diagram illustrating a distributed data processing environment, generally designated 100, in accordance with an embodiment of the present invention. In the depicted embodiment, distributed data processing environment 100 includes server 120, user computing device 130, sensors 140_{1-N}, and external scanning component 150, interconnected over network 110. Distributed data processing environment 100 may include additional servers, computers, computing devices, IoT sensors, and other devices not shown. The term “distributed” as used herein describes a computer system that includes multiple, physically distinct devices that operate together as a single computer system. FIG. 1 provides only an illustration of one embodiment of the present invention and does not imply any limitations with regards to the environments in which different embodiments may be implemented. Many modifications to the depicted environment may be made by those skilled in the art without departing from the scope of the invention as recited by the claims.

Network 110 operates as a computing network that can be, for example, a telecommunications network, a local area network (LAN), a wide area network (WAN), such as the Internet, or a combination of the three, and can include wired, wireless, or fiber optic connections. Network 110 can include one or more wired and/or wireless networks capable of receiving and transmitting data, voice, and/or video signals, including multimedia signals that include data, voice, and video information. In general, network 110 can be any combination of connections and protocols that will support communications between server 120, user computing device 130, sensors 140_{1-N}, external scanning component 150, and other computing devices (not shown) within distributed data processing environment 100.

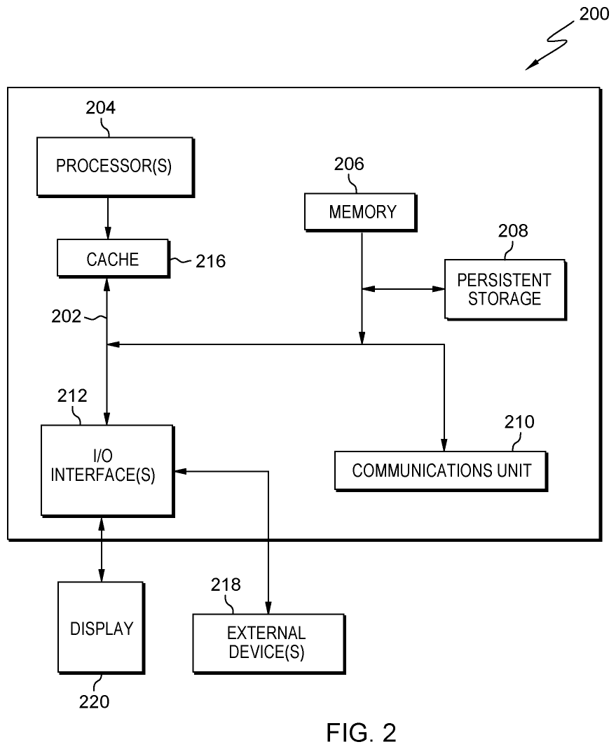

Server 120 operates to run optimized digital twin creation program 122 and to send and/or store data in database 124. In an embodiment, server 120 can send data from database 124 to user computing device 130, sensors 140_{1-N}, and external scanning component 150. In an embodiment, server 120 can receive data in database 124 from user computing device 130, sensors 140_{1-N}, and external scanning component 150. In one or more embodiments, server 120 can be a standalone computing device, a management server, a web server, a mobile computing device, or any other electronic device or computing system capable of receiving, sending, and processing data and capable of communicating with user computing device 130, sensors 140_{1-N}, and external scanning component 150 via network 110. In one or more embodiments, server 120 can be a computing system utilizing clustered computers and components (e.g., database server computers, application server computers, etc.) that act as a single pool of seamless resources when accessed within distributed data processing environment 100, such as in a cloud computing environment. In one or more embodiments, server 120 can be a laptop computer, a tablet computer, a netbook computer, a personal computer, a desktop computer, a personal digital assistant, a smart phone, or any programmable electronic device capable of communicating with user computing device 130, sensors 140_{1-N}, external scanning component 150, and other computing devices (not shown) within distributed data processing environment 100 via network 110. Server 120 may include internal and external hardware components, as depicted and described in further detail in FIG. 2.

Optimized digital twin creation program 122 operates to build a subset of digital twin models based on a contextual need to perform a simulation for a derived activity surrounding and relative data gathered from various sensors placed within that surrounding. In the depicted embodiment, optimized digital twin creation program 122 is a standalone program. In another embodiment, optimized digital twin creation program 122 may be integrated into another software product, such as an asset management software. In the depicted embodiment, optimized digital twin creation program 122 contains set-up component 122-B. Set-up component 122-B operates to create a digital twin model of a machine. In the depicted embodiment, optimized digital twin creation program 122 resides on server 120. In another embodiment, optimized digital twin creation program 122 may reside on user computing device 130 or on another computing device (not shown), provided that optimized digital twin creation program 122 has access to network 110.

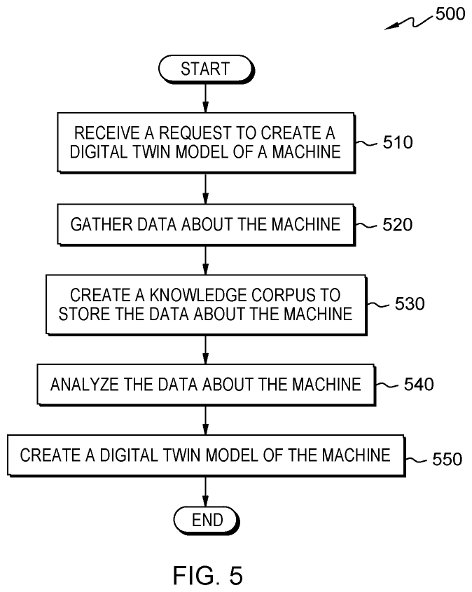

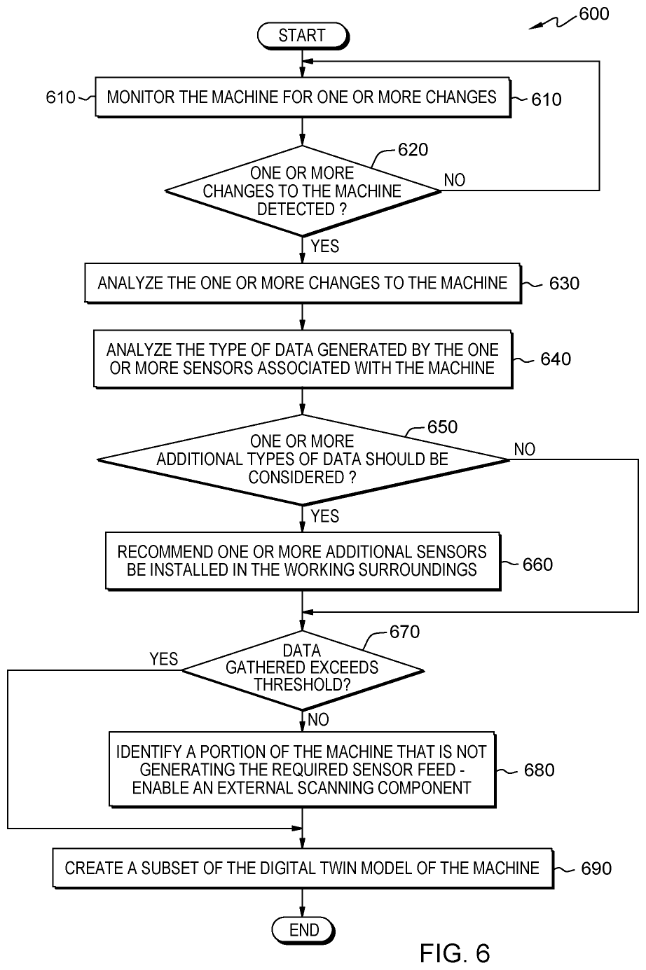

In an embodiment, the user of user computing device 130 registers with optimized digital twin creation program 122 of server 120. For example, the user completes a registration process (e.g., user validation), provides information to create a user profile, and authorizes the collection, analysis, and distribution (i.e., opts-in) of relevant data on identified computing devices (e.g., on user computing device 130) by server 120 (e.g., via optimized digital twin creation program 122). Relevant data includes, but is not limited to, personal information or data provided by the user or inadvertently provided by the user's device without the user's knowledge; tagged and/or recorded location information of the user (e.g., to infer context (i.e., time, place, and usage) of a location or existence); time stamped temporal information (e.g., to infer contextual reference points); and specifications pertaining to the software or hardware of the user's device. In an embodiment, the user opts-in or opts-out of certain categories of data collection. For example, the user can opt-in to provide all requested information, a subset of requested information, or no information. In one example scenario, the user opts-in to provide time-based information, but opts-out of providing location-based information (on all or a subset of computing devices associated with the user). In an embodiment, the user opts-in or opts-out of certain categories of data analysis. In an embodiment, the user opts-in or opts-out of certain categories of data distribution. Such preferences can be stored in database 124. The operational steps of setup component 122-B of optimized digital twin creation program 122 are depicted and described in further detail with respect to FIG. 5. The operational steps of optimized digital twin creation program 122 are depicted and described in further detail with respect to FIG. 6.

Database 124 operates as a repository for data received, used, and/or generated by optimized digital twin creation program 122. A database is an organized collection of data. Data includes, but is not limited to, information about user preferences (e.g., general user system settings such as alert notifications for user computing device 130); information about alert notification preferences; historical data about a machine; knowledge corpus of data gathered about the machine (i.e., an adaptability of the machine; one or more types of working surroundings in which the machine is found; one or more activities performed by the machine; a type of data generated by the one or more sensors (e.g., sensor 140_{1-N}) associated with the machine; a volume of data generated by the one or more sensors (e.g., sensor 140_{1-N}) associated with the machine; one or more types of data used in the creation of the digital twin model of the machine; one or more factors that influenced the creation of the digital twin; one or more environmental factors that affected the creation of the digital twin); a digital twin model of the machine; a subset of the digital twin model of the machine; and any other data received, used, and/or generated by optimized digital twin creation program 122.

Database 124 can be implemented with any type of device capable of storing data and configuration files that can be accessed and utilized by server 120, such as a hard disk drive, a database server, or a flash memory. In an embodiment, database 124 is accessed by optimized digital twin creation program 122 to store and/or to access the data. In the depicted embodiment, database 124 resides on server 120. In another embodiment, database 124 may reside on another computing device, server, cloud server, or spread across multiple devices elsewhere (not shown) within distributed data processing environment 100, provided that optimized digital twin creation program 122 has access to database 124.

The present invention may contain various accessible data sources, such as database 124, that may include personal and/or confidential company data, content, or information the user wishes not to be processed. Processing refers to any operation, automated or unautomated, or set of operations such as collecting, recording, organizing, structuring, storing, adapting, altering, retrieving, consulting, using, disclosing by transmission, dissemination, or otherwise making available, combining, restricting, erasing, or destroying personal and/or confidential company data. Optimized digital twin creation program 122 enables the authorized and secure processing of personal data.

Optimized digital twin creation program 122 provides informed consent, with notice of the collection of personal and/or confidential data, allowing the user to opt-in or opt-out of processing personal and/or confidential data. Consent can take several forms. Opt-in consent can impose on the user to take an affirmative action before personal and/or confidential data is processed. Alternatively, opt-out consent can impose on the user to take an affirmative action to prevent the processing of personal and/or confidential data before personal and/or confidential data is processed. Optimized digital twin creation program 122 provides information regarding personal and/or confidential data and the nature (e.g., type, scope, purpose, duration, etc.) of the processing. Optimized digital twin creation program 122 provides the user with copies of stored personal and/or confidential company data. Optimized digital twin creation program 122 allows the correction or completion of incorrect or incomplete personal and/or confidential data. Optimized digital twin creation program 122 allows for the immediate deletion of personal and/or confidential data.

User computing device 130 operates to run user interface 132 through which a user can interact with optimized digital twin creation program 122 on server 120. In an embodiment, user computing device 130 is a device that performs programmable instructions. For example, user computing device 130 may be an electronic device, such as a laptop computer, a tablet computer, a netbook computer, a personal computer, a desktop computer, a smart phone, or any programmable electronic device capable of running user interface 132 and of communicating (i.e., sending and receiving data) with optimized digital twin creation program 122 via network 110. In general, user computing device 130 represents any programmable electronic device or a combination of programmable electronic devices capable of executing machine readable program instructions and communicating with other computing devices (not shown) within distributed data processing environment 100 via network 110. In the depicted embodiment, user computing device 130 includes an instance of user interface 132.

User interface 132 operates as a local user interface between optimized digital twin creation program 122 on server 120 and a user of user computing device 130. In some embodiments, user interface 132 is a graphical user interface (GUI), a web user interface (WUI), and/or a voice user interface (VUI) that can display (i.e., visually) or present (i.e., audibly) text, documents, web browser windows, user options, application interfaces, and instructions for operations sent from optimized digital twin creation program 122 to a user via network 110. User interface 132 can also display or present alerts including information (such as graphics, text, and/or sound) sent from optimized digital twin creation program 122 to a user via network 110. In an embodiment, user interface 132 is capable of sending and receiving data (i.e., to and from optimized digital twin creation program 122 via network 110, respectively). Through user interface 132, a user can opt-in to optimized digital twin creation program 122; create a user profile; set user preferences and alert notification preferences; input a request to create a digital twin model of a machine; input data about the machine; interact with a digital twin model of the machine; interact with a subset of the digital twin model of the machine; receive a request for feedback; and input feedback.

A user preference is a setting that can be customized for a particular user. A set of default user preferences are assigned to each user of optimized digital twin creation program 122. A user preference editor can be used to update values to change the default user preferences. User preferences that can be customized include, but are not limited to, general user system settings, specific user profile settings, alert notification settings, and machine-learned data collection/storage settings. Machine-learned data is a user's personalized corpus of data. Machine-learned data includes, but is not limited to, past results of iterations of optimized digital twin creation program 122.

Sensors 140_{1-N} operate to capture data from the machine and from the working surroundings in which the machine is found. Additionally, sensors 140_{1-N} operate to output the data captured from the machine and from the working surroundings in which the machine is found to optimized digital twin creation program 122. As used herein, N represents a positive integer, and accordingly the number of scenarios implemented in a given embodiment of the present invention is not limited to those depicted in FIG. 1. In the depicted embodiment, sensors 140_{1-N} are separate components. In another embodiment, sensors 140_{1-N} may be integrated into a computing device, server, cloud server, or spread across multiple devices elsewhere (not shown) within distributed data processing environment 100, provided that sensors 140_{1-N} have access to database 124.

External scanning component 150 operates to capture a set of data from the portion of the machine that is not able to generate the required sensor feed. In the depicted embodiment, external scanning component 150 is a separate component. In another embodiment, external scanning component 150 may be integrated into a computing device, server, cloud server, or spread across multiple devices elsewhere (not shown) within distributed data processing environment 100, provided that external scanning component 150 has access to database 124.

FIG. 2 is a block diagram illustrating the components of computing device 200, suitable for server 120 running optimized digital twin creation program 122 within distributed data processing environment 100 of FIG. 1, in accordance with an embodiment of the present invention. It should be appreciated that FIG. 2 provides only an illustration of one implementation and does not imply any limitations with regard to the environments in which different embodiments can be implemented. Many modifications to the depicted environment can be made.

As depicted, computing device 200 includes communications fabric 202, processor(s) 204, memory 206, persistent storage 208, communications unit 210, input/output (I/O) interface(s) 212, and cache 216. Communications fabric 202 provides communications between memory 206, cache 216, persistent storage 208, input/output (I/O) interface(s) 212, and communications unit 210. Communications fabric 202 can be implemented with any architecture designed for passing data and/or control information between processors (such as microprocessors, communications and network processors, etc.), system memory, peripheral devices, and any other hardware components within a system. For example, communications fabric 202 can be implemented with one or more buses or a cross switch.

Memory 206 and persistent storage 208 are computer readable storage media. In this embodiment, memory 206 includes random access memory (RAM). In general, memory 206 can include any suitable volatile or non-volatile computer readable storage media. Cache 216 is a fast memory that enhances the performance of computer processor(s) 204 by holding recently accessed data, and data near accessed data, from memory 206.

Program instructions and data (e.g., software and data) used to practice embodiments of the present invention may be stored in persistent storage 208 and in memory 206 for execution by one or more of the respective processor(s) 204 via cache 216. In an embodiment, persistent storage 208 includes a magnetic hard disk drive. Alternatively, or in addition to a magnetic hard disk drive, persistent storage 208 can include a solid-state hard drive, a semiconductor storage device, a read-only memory (ROM), an erasable programmable read-only memory (EPROM), a flash memory, or any other computer readable storage media that is capable of storing program instructions or digital information.

The media used by persistent storage 208 may also be removable. For example, a removable hard drive may be used for persistent storage 208. Other examples include optical and magnetic disks, thumb drives, and smart cards that are inserted into a drive for transfer onto another computer readable storage medium that is also part of persistent storage 208. Software and data can be stored in persistent storage 208 for access and/or execution by one or more of the respective processor(s) 204 via cache 216. With respect to user computing device 130, software and data includes user interface 132. With respect to server 120, software and data includes optimized digital twin creation program 122.

Communications unit 210, in these examples, provides for communications with other data processing systems or devices. In these examples, communications unit 210 includes one or more network interface cards. Communications unit 210 may provide communications through the use of either or both physical and wireless communications links. Program instructions and data (e.g., software and data) used to practice embodiments of the present invention may be downloaded to persistent storage 208 through communications unit 210.

I/O interface(s) 212 allows for input and output of data with other devices that may be connected to each computer system. For example, I/O interface(s) 212 may provide a connection to external device(s) 218, such as a keyboard, a keypad, a touch screen, and/or some other suitable input device. External device(s) 218 can also include portable computer readable storage media, such as, for example, thumb drives, portable optical or magnetic disks, and memory cards. Program instructions and data (e.g., software and data) used to practice embodiments of the present invention can be stored on such portable computer readable storage media and can be loaded onto persistent storage 208 via I/O interface(s) 212. I/O interface(s) 212 also connect to display 220.

Display 220 provides a mechanism to display data to a user and may be, for example, a computer monitor.

It is to be understood that although this disclosure includes a detailed description on cloud computing, implementation of the teachings recited herein are not limited to a cloud computing environment. Rather, embodiments of the present invention are capable of being implemented in conjunction with any other type of computing environment now known or later developed.

Cloud computing is a model of service delivery for enabling convenient, on-demand network access to a shared pool of configurable computing resources (e.g., networks, network bandwidth, servers, processing, memory, storage, applications, virtual machines, and services) that can be rapidly provisioned and released with minimal management effort or interaction with a provider of the service. This cloud model may include at least five characteristics, at least three service models, and at least four deployment models.

Characteristics are as follows:

On-demand self-service: a cloud consumer can unilaterally provision computing capabilities, such as server time and network storage, as needed automatically without requiring human interaction with the service's provider.

Broad network access: capabilities are available over a network and accessed through standard mechanisms that promote use by heterogeneous thin or thick client platforms (e.g., mobile phones, laptops, and PDAs).

Resource pooling: the provider's computing resources are pooled to serve multiple consumers using a multi-tenant model, with different physical and virtual resources dynamically assigned and reassigned according to demand. There is a sense of location independence in that the consumer generally has no control or knowledge over the exact location of the provided resources but may be able to specify location at a higher level of abstraction (e.g., country, state, or datacenter).

Rapid elasticity: capabilities can be rapidly and elastically provisioned, in some cases automatically, to quickly scale out and rapidly released to quickly scale in. To the consumer, the capabilities available for provisioning often appear to be unlimited and can be purchased in any quantity at any time.

Measured service: cloud systems automatically control and optimize resource use by leveraging a metering capability at some level of abstraction appropriate to the type of service (e.g., storage, processing, bandwidth, and active user accounts). Resource usage can be monitored, controlled, and reported, providing transparency for both the provider and consumer of the utilized service.

Service Models are as follows:

Software as a Service (SaaS): the capability provided to the consumer is to use the provider's applications running on a cloud infrastructure. The applications are accessible from various client devices through a thin client interface such as a web browser (e.g., web-based e-mail). The consumer does not manage or control the underlying cloud infrastructure including network, servers, operating systems, storage, or even individual application capabilities, with the possible exception of limited user-specific application configuration settings.

Platform as a Service (PaaS): the capability provided to the consumer is to deploy onto the cloud infrastructure consumer-created or acquired applications created using programming languages and tools supported by the provider. The consumer does not manage or control the underlying cloud infrastructure including networks, servers, operating systems, or storage, but has control over the deployed applications and possibly application hosting environment configurations.

Infrastructure as a Service (IaaS): the capability provided to the consumer is to provision processing, storage, networks, and other fundamental computing resources where the consumer is able to deploy and run arbitrary software, which can include operating systems and applications. The consumer does not manage or control the underlying cloud infrastructure but has control over operating systems, storage, deployed applications, and possibly limited control of select networking components (e.g., host firewalls).

Deployment Models are as follows:

Private cloud: the cloud infrastructure is operated solely for an organization. It may be managed by the organization or a third party and may exist on-premises or off-premises.

Community cloud: the cloud infrastructure is shared by several organizations and supports a specific community that has shared concerns (e.g., mission, security requirements, policy, and compliance considerations). It may be managed by the organizations or a third party and may exist on-premises or off-premises.

Public cloud: the cloud infrastructure is made available to the general public or a large industry group and is owned by an organization selling cloud services.

Hybrid cloud: the cloud infrastructure is a composition of two or more clouds (private, community, or public) that remain unique entities but are bound together by standardized or proprietary technology that enables data and application portability (e.g., cloud bursting for load-balancing between clouds).

A cloud computing environment is service oriented with a focus on statelessness, low coupling, modularity, and semantic interoperability. At the heart of cloud computing is an infrastructure that includes a network of interconnected nodes.

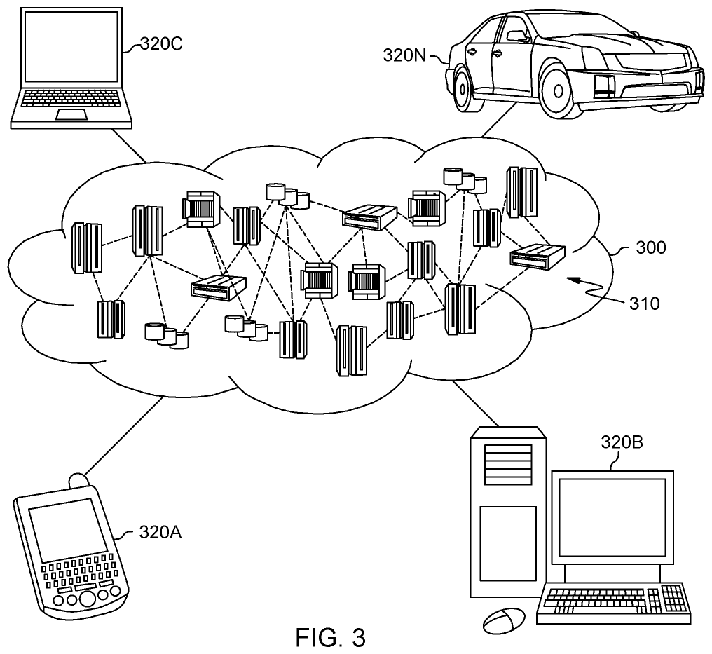

FIG. 3 is a block diagram illustrating an exemplary cloud computing environment, generally designated cloud computing environment 300, in accordance with an embodiment of the present invention. As shown, cloud computing environment 300 includes one or more cloud computing nodes 310 with which local computing devices used by cloud consumers, such as, for example, personal digital assistant (PDA) or cellular telephone 320A, desktop computer 320B, laptop computer 320C, and/or automobile computer system 320N may communicate. Nodes 310 may communicate with one another. They may be grouped (not shown) physically or virtually, in one or more networks, such as Private, Community, Public, or Hybrid clouds as described hereinabove, or a combination thereof. This allows cloud computing environment 300 to offer infrastructure, platforms, and/or software as services for which a cloud consumer does not need to maintain resources on a local computing device. It is understood that the types of computing devices 320A-N shown in FIG. 3 are intended to be illustrative only and that computing nodes 310 and cloud computing environment 300 can communicate with any type of computerized device over any type of network and/or network addressable connection (e.g., using a web browser).

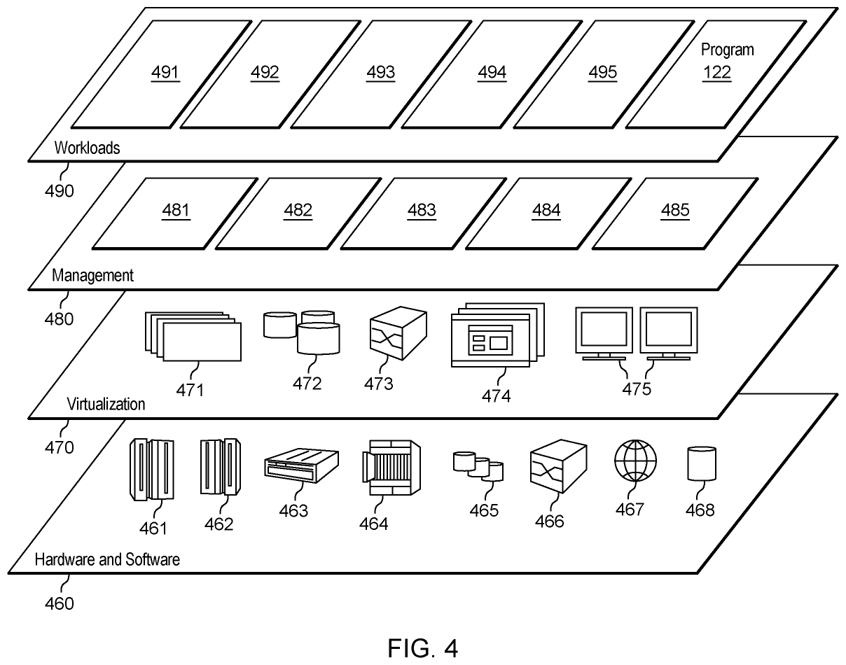

FIG. 4 is a block diagram illustrating a set of functional abstraction model layers, generally designated 400, of the exemplary cloud computing environment (e.g., cloud computing environment 300), in accordance with an embodiment of the present invention. It should be understood in advance that the components, layers, and functions shown in FIG. 4 are intended to be illustrative only and embodiments of the invention are not limited thereto. As depicted, the following layers and corresponding functions are provided:

Hardware and software layer 460 includes hardware and software components. Examples of hardware components include: mainframes 461; RISC (Reduced Instruction Set Computer) architecture based servers 462; servers 463; blade servers 464; storage devices 465; and networks and networking components 466. In some embodiments, software components include network application server software 467 and database software 468.

Virtualization layer 470 provides an abstraction layer from which the following examples of virtual entities may be provided: virtual servers 471; virtual storage 472; virtual networks 473, including virtual private networks; virtual applications and operating systems 474; and virtual clients 475.

In one example, management layer 480 may provide the functions described below. Resource provisioning 481 provides dynamic procurement of computing resources and other resources that are utilized to perform tasks within the cloud computing environment. Metering and Pricing 482 provide cost tracking as resources are utilized within the cloud computing environment, and billing or invoicing for consumption of these resources. In one example, these resources may include application software licenses. Security provides identity verification for cloud consumers and tasks, as well as protection for data and other resources. User portal 483 provides access to the cloud computing environment for consumers and system administrators. Service level management 484 provides cloud computing resource allocation and management such that required service levels are met. Service Level Agreement (SLA) planning and fulfillment 485 provides pre-arrangement for, and procurement of, cloud computing resources for which a future requirement is anticipated in accordance with an SLA.

Workloads layer 490 provides examples of functionality for which the cloud computing environment may be utilized. Examples of workloads and functions which may be provided from this layer include: mapping and navigation 491; software development and lifecycle management 492; virtual classroom education delivery 493; data analytics processing 494; transaction processing 495; and, in the context of the illustrated embodiments of the present invention, various optimization workloads and functions 496.

FIG. 5 is a flowchart, generally designated 500, illustrating the operational steps for setup component 122-B of optimized digital twin creation program 122 (hereinafter referred to as “program 122”), on server 120 within distributed data processing environment 100 of FIG. 1, in accordance with an embodiment of the present invention. In an embodiment, setup component 122-B of program 122 operates to create a digital twin model of a machine. It should be appreciated that the process depicted in FIG. 5 illustrates one possible iteration of the process flow, which may be repeated for each request received.

In step 510, setup component 122-B of program 122 receives a request. In an embodiment, setup component 122-B of program 122 receives a request to create a digital twin model of a machine. A machine is an apparatus using or applying mechanical power and having several parts, each with a definite function and together performing a particular task. In addition to an apparatus, a machine may be, but is not limited to, a physical asset, an appliance, an instrument, a tool, a device, a unit, a contraption, a gadget, a mechanism, an engine, a motor, a lever, or a pulley. In an embodiment, setup component 122-B of program 122 receives the request from a user of a user computing device (e.g., user computing device 130) via a user interface (e.g., user interface 132).

In step 520, setup component 122-B of program 122 gathers data about the machine. In an embodiment, responsive to receiving the request to create the digital twin model of the machine, setup component 122-B of program 122 gathers data about the machine. In an embodiment, setup component 122-B of program 122 gathers data about the machine from the user of the user computing device (e.g., user computing device 130) via the user interface (e.g., user interface 132). In an embodiment, setup component 122-B of program 122 gathers data about the machine (e.g., historical data) from a database (e.g., database 124). In an embodiment, setup component 122-B of program 122 gathers data from the machine via one or more sensors (e.g., sensor 140_{1-N}) associated with the machine (i.e., one or more sensors from which data is outputted from the machine and one or more sensors from which data is outputted from the working surroundings (i.e., contextual situations) in which the machine is found).

In step 530, setup component 122-B of program 122 creates a knowledge corpus. In an embodiment, responsive to gathering data about the machine, setup component 122-B of program 122 creates a knowledge corpus. In an embodiment, setup component 122-B of program 122 creates a knowledge corpus exclusively for data gathered about the machine. In an embodiment, setup component 122-B of program 122 creates a knowledge corpus in a database (e.g., database 124). In an embodiment, setup component 122-B of program 122 stores the data gathered in the knowledge corpus.

In step 540, setup component 122-B of program 122 analyzes the data gathered. In an embodiment, responsive to gathering data about the machine, setup component 122-B of program 122 analyzes the data gathered. In an embodiment, setup component 122-B of program 122 compares the data gathered to historical data stored in a database (e.g., database 124). In an embodiment, setup component 122-B of program 122 identifies one or more correlations in the data. In an embodiment, setup component 122-B of program 122 learns from the one or more correlations in the data. In an embodiment, setup component 122-B of program 122 evaluates the adaptability of the machine. In an embodiment, setup component 122-B of program 122 predicts one or more types of working surroundings in which the machine is found. In an embodiment, setup component 122-B of program 122 predicts one or more activities performed by the machine. In an embodiment, setup component 122-B of program 122 predicts a type of data generated by the one or more sensors (e.g., sensors 140_{1-N}) associated with the machine. In an embodiment, setup component 122-B of program 122 predicts a volume of data generated by the one or more sensors (e.g., sensors 140_{1-N}) associated with the machine.

In step 550, setup component 122-B of program 122 creates a digital twin model of the machine. In an embodiment, responsive to analyzing the data gathered, setup component 122-B of program 122 creates a digital twin model of the machine. In an embodiment, setup component 122-B of program 122 identifies one or more types of data used in the creation of the digital twin model of the machine. In an embodiment, setup component 122-B of program 122 identifies one or more factors that influenced the creation of the digital twin model of the machine. In an embodiment, setup component 122-B of program 122 identifies one or more environmental factors that affected the creation of the digital twin model of the machine. In an embodiment, setup component 122-B of program 122 stores the one or more factors identified in the knowledge corpus.

FIG. 6 is a flowchart, generally designated 600, illustrating the operational steps for program 122, on server 120 within distributed data processing environment 100 of FIG. 1, in accordance with an embodiment of the present invention. In an embodiment, program 122 operates to build a subset of digital twin models based on a contextual need to perform a simulation for a derived activity surrounding and relative data gathered from various sensors placed within that surrounding. It should be appreciated that the process depicted in FIG. 6 illustrates one possible iteration of the process flow, which may be repeated for each change to the machine detected during the life-cycle of the machine.

In step 610, program 122 monitors the machine and/or the digital twin (i.e., created in FIG. 5) for one or more changes. In an embodiment, program 122 monitors the machine and/or the digital twin for one or more changes continuously for the life-cycle of the machine.

In decision step 620, program 122 determines whether one or more changes to the machine have been detected. In an embodiment, responsive to monitoring the machine and/or the digital twin for one or more changes, program 122 determines whether one or more changes to the machine have been detected. In an embodiment, program 122 determines whether one or more changes to the machine have been detected from a comparison of the current data to the data stored in the knowledge corpus. In an embodiment, program 122 detects a change to the machine when an activity performed by the machine in a working surrounding has changed. In another embodiment, program 122 detects a change to the machine when the one or more working surroundings in which the machine is found have changed. In another embodiment, program 122 detects a change to the machine when the type of data generated by the one or more sensors (e.g., sensors 140_{1-N}) associated with the machine when performing an activity in a working surrounding has changed. In another embodiment, program 122 detects a change to the machine when the volume of data generated by the one or more sensors (e.g., sensors 140_{1-N}) associated with the machine in a particular working surrounding has changed. If program 122 determines one or changes to the machine have been detected (decision step 620, YES branch), then program 122 proceeds to step 630, analyzing the one or more changes to the machine. If program 122 determines one or changes to the machine have not been detected (decision step 620, NO branch), then program 122 continues to monitor the machine for one or more changes.

In step 630, program 122 analyzes the one or more changes to the machine. In an embodiment, responsive to determining one or changes to the machine have been detected, program 122 analyzes the one or more changes to the machine.

In an embodiment, program 122 analyzes the one or more activities the machine is currently performing. In an embodiment, program 122 determines whether the one or more activities performed by the machine have changed. In an embodiment, program 122 determines whether the one or more activities performed by the machine have changed based on the digital twin. In other words, program 122 determines whether the working behavior of the machine has been affected by the one or more changes to the machine. In an embodiment, responsive to determining the one or more activities performed by the machine have changed, program 122 identifies the one or more changes to the one or more activities performed by the machine.

In an embodiment, program 122 analyzes the type of working surroundings in which the machine is found. In an embodiment, program 122 determines whether the working surroundings have changed. In an embodiment, program 122 determines whether the working surroundings have changed based on the digital twin. In an embodiment, responsive to determining the working surroundings have changed, program 122 identifies the changes in the working surroundings. In an embodiment, program 122 refers to the data stored in the knowledge corpus to identify the activities that should be performed in the changed working surrounding.

In step 640, program 122 analyzes the data generated by the one or more sensors (e.g., sensors 140_{1-N}) associated with the machine. In an embodiment, responsive to analyzing the one or more changes to the machine, program 122 analyzes the data generated by the one or more sensors (e.g., sensors 140_{1-N}) associated with the machine. In an embodiment, program 122 determines whether the type of data generated by the one or more sensors (e.g., sensors 140_{1-N}) associated with the machine has changed based on the digital twin (i.e., whether the same type of data or a different type of data is required). In an embodiment, program 122 determines whether the priority level of the type of data generated by the one or more sensors (e.g., sensors 140_{1-N}) associated with the machine has changed based on the digital twin (e.g., a type of data generated is no longer required for the activity the machine is now performing and, therefore, will not be included when building the subset of the digital twin model of the machine). In an embodiment, program 122 determines the type of data required to create a subset of the digital twin model of the machine (i.e., the required sensor feed) from the one or more sensors (e.g., sensors 140_{1-N}) associated with the machine.

For example, program 122 detects a change to the machine. A protective cover has been applied to the machine. The protective cover prevents oil and water corrosion. Program 122, however, determines the protective cover changes the working behavior of the machine, which in turn changes the productivity of the machine. Additionally, program 122 determines that weather data is no longer required for the creation of the digital twin of the machine and, therefore, the priority level of the weather data should be changed.

In decision step 650, program 122 determines whether the one or more sensors (e.g., sensors 140_{1-N}) associated with the machine can generate the required data. In an embodiment, responsive to analyzing the data generated by the one or more sensors (e.g., sensors 140_{1-N}) associated with the machine, program 122 determines whether the one or more sensors (e.g., sensors 140_{1-N}) associated with the machine can generate the required type of data. In an embodiment, program 122 determines whether the one or more sensors (e.g., sensors 140_{1-N}) associated with the machine can generate the required type of data based on the digital twin. In an embodiment, program 122 determines whether one or more additional types of data should be considered. If program 122 determines one or more additional types of data should be considered (decision step 650, YES branch), then program 122 proceeds to step 660, proactively installing one or more additional sensors (e.g., sensors 140_{1-N}) in the working surroundings in which the machine is found. If program 122 determines one or more additional types of data should not be considered (decision step 650, NO branch), then program 122 proceeds to step 670, analyzing the data gathered from the one or more sensors (e.g., sensors 140_{1-N}) in the working surroundings in which the machine is found.

In step 660, program 122 recommends one or more additional sensors be installed in the working surroundings in which the machine is found. In an embodiment, responsive to determining one or more additional types of data should be considered, program 122 recommends one or more additional sensors be installed in the working surroundings in which the machine is found. In an embodiment, program 122 proactively installs one or more additional sensors (e.g., sensors 140_{N+N}) in the working surroundings in which the machine is found. In another embodiment, program 122 enables the user to install one or more additional sensors (e.g., sensors 140_{N+N}) in the working surroundings in which the machine is found. The one or more additional sensors installed capture the working surroundings properly so that the data from the working surroundings can be captured and included when building the subset of the digital twin model of the machine (i.e., for a complete digital twin simulation).

In decision step 670, program 122 determines an amount of data required to create a subset of the digital twin model of the machine. In an embodiment, responsive to recommending one or more additional sensors be installed in the working surroundings in which the machine is found, program 122 determines an amount of data required to create a subset of the digital twin model of the machine. In an embodiment, program 122 determines an amount of data required to create a subset of the digital twin model of the machine (i.e., the required sensor feed) from the one or more sensors (e.g., sensors 140_{1-N}) associated with the machine. In an embodiment, program 122 analyzes the data gathered from the one or more sensors (and the one or more additional sensors in some embodiments) in the working surroundings in which the machine is found. In an embodiment, program 122 determines whether the data gathered exceeds a pre-set threshold amount of data required to create a subset of the digital twin model of the machine. If program 122 determines the data gathered exceeds the pre-set threshold amount of data required (decision step 670, YES branch), then program 122 enables the one or more sensors (and the one or more additional sensors in some embodiments) in the working surroundings to continue to generate data. If program 122 determines the data gathered does not exceed the pre-set threshold amount of data required (decision step 670, NO branch), then program 122 proceeds to step 680, analyzing a portion of the machine that is not able to generate the required sensor feed.

In step 680, program 122 identifies a portion of the machine that is not able to generate the required sensor feed. In an embodiment, responsive to determining the data gathered does not exceed the pre-set threshold amount of data required, program 122 identifies a portion of the machine that is not able to generate the required sensor feed. In an embodiment, program 122 identifies a portion of the machine that is not able to generate the required sensor feed based on the analyzation of the data gathered from the one or more sensors (and the one or more additional sensors in some embodiments) in the working surroundings in which the machine is found. In an embodiment, program 122 analyzes a portion of the machine that is not able to generate the required sensor feed. In an embodiment, program 122 enables external scanning component 150 to capture a set of data from the portion of the machine that is not able to generate the required sensor feed.

In step 690, program 122 creates a subset of the digital twin model of the machine. In an embodiment, responsive to analyzing a portion of the machine that is not able to generate the required sensor feed, program 122 creates a subset of the digital twin model of the machine. The subset incorporates the one or more changes made to the machine. When creating a digital twin model of a machine or device, all possible sensor feeds are used. However, all possible sensor feeds are not necessary in every contextual situation. Rather, each contextual situation requires a different set of sensor feeds. If all possible sensor feeds are used when creating a digital twin model of a machine, then an increase in the volume of data will occur and will require additional processing capabilities and time. Therefore, the subset is an optimal version of the digital twin model of the machine. The subset is created using an appropriate set of internal and external influencing factors. The subset is based on a contextual need to perform a simulation for a derived activity surrounding and relative data gathered from various sensors placed within that surrounding.

The programs described herein are identified based upon the application for which they are implemented in a specific embodiment of the invention. However, it should be appreciated that any particular program nomenclature herein is used merely for convenience, and thus the invention should not be limited to use solely in any specific application identified and/or implied by such nomenclature.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

While particular embodiments of the present invention have been shown and described here, it will be understood to those skilled in the art that, based upon the teachings herein, changes and modifications may be made without departing from the embodiments and its broader aspects. Therefore, the appended claims are to encompass within their scope all such changes and modifications as are within the true spirit and scope of the embodiments. Furthermore, it is to be understood that the embodiments are solely defined by the appended claims. It will be understood by those with skill in the art that if a specific number of an introduced claim element is intended, such intent will be explicitly recited in the claim, and in the absence of such recitation no such limitation is present. For a non-limiting example, as an aid to understand, the following appended claims contain usage of the introductory phrases “at least one” and “one or more” to introduce claim elements. However, the use of such phrases should not be construed to imply that the introduction of a claim element by the indefinite articles “a” or “an” limits any particular claim containing such introduced claim element to embodiments containing only one such element, even when the same claim includes the introductory phrases “at least one” or “one or more” and indefinite articles such as “a” or “an”, the same holds true for the use in the claims of definite articles.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart illustrations and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart illustrations and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart illustrations and/or block diagram block or blocks.

The flowchart illustrations and block diagrams in the Figures illustrate the architecture, functionality, and operation of possible implementations of systems, methods, and computer program products according to various embodiments of the present invention. In this regard, each block in the flowchart illustrations or block diagrams may represent a module, segment, or portion of instructions, which comprises one or more executable instructions for implementing the specified logical function(s). In some alternative implementations, the functions noted in the block may occur out of the order noted in the Figures. For example, two blocks shown in succession may, in fact, be executed substantially concurrently, or the blocks may sometimes be executed in the reverse order, depending upon the functionality involved. It will also be noted that each flowchart illustration and/or block of the block diagrams, and combinations of flowchart illustration and/or blocks in the block diagrams, can be implemented by special purpose hardware-based systems that perform the specified functions or acts or carry out combinations of special purpose hardware and computer instructions.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A computer-implemented method comprising:
monitoring, by one or more processors, a digital twin model of a machine for one or more changes to the machine;
responsive to detecting a change to the machine, analyzing, by the one or more processors, one or more aspects of the machine, wherein the one or more aspects of the machine include a contextual situation of the machine and one or more activities performed by the machine in the contextual situation;
responsive to determining the contextual situation of the machine has changed, analyzing, by the one or more processors, one or more sensors associated with the machine and a first set of data generated by the one or more sensors associated with the machine;
determining, by the one or more processors, the one or more sensors associated with the machine are generating a required type of data and a required amount of data to create a subset of the digital twin model of the machine; and
creating, by the one or more processors, the subset of the digital twin model of the machine incorporating the change detected.

2. The computer-implemented method of claim 1, further comprising:
prior to monitoring the digital twin model of the machine for the one or more changes to the machine, receiving, by the one or more processors, a request to create the digital twin model of the machine;
gathering, by the one or more processors, a second set of data about the machine; and
creating, by the one or more processors, the digital twin model of the machine.

3. The computer-implemented method of claim 2, wherein gathering the second set of data about the machine further comprises:
analyzing, by the one or more processors, the second set of data to evaluate an adaptability of the machine;
analyzing, by the one or more processors, the second set of data to predict the contextual situation of the machine;
analyzing, by the one or more processors, the second set of data to predict the one or more activities performed by the machine in the contextual situation;
analyzing, by the one or more processors, the second set of data to predict a type of data generated by the one or more sensors associated with the machine; and
analyzing, by the one or more processors, the second set of data to predict a volume of the type of data predicted to be generated by the one or more sensors associated with the machine.

4. The computer-implemented method of claim 3, further comprising:
storing, by the one or more processors, the second set of data about the machine in a knowledge corpus.

5. The computer-implemented method of claim 1, wherein analyzing the one or more sensors associated with the machine and the first set of data generated by the one or more sensors associated with the machine further comprises:
determining, by the one or more processors, whether the type of data generated by the one or more sensors associated with the machine has changed; and
determining, by the one or more processors, whether a priority level of the type of data generated by the one or more sensors associated with the machine has changed.

6. The computer-implemented method of claim 1, further comprising:
determining, by the one or more processors, the one or more sensors associated with the machine are not generating the required type of data to create the subset of the digital twin model of the machine based on the digital twin;
recommending, by the one or more processors, one or more additional sensors be installed in the contextual situation of the machine; and
proactively installing, by the one or more processors, one or more additional sensors in the contextual situation of the machine.

7. The computer-implemented method of claim 1, further comprising:
determining, by the one or more processors, the one or more sensors associated with the machine are not generating the required amount of data to create the subset of the digital twin model of the machine based on the digital twin; and
enabling, by the one or more processors, an external scanning component to generate the required amount of data to create the subset of the digital twin model of the machine.

8. A computer program product comprising:
one or more computer readable storage media and program instructions stored on the one or more computer readable storage media, the program instructions comprising:
program instructions to monitor a digital twin model of a machine for one or more changes to the machine;
responsive to detecting a change to the machine, program instructions to analyze one or more aspects of the machine, wherein the one or more aspects of the machine include a contextual situation of the machine and one or more activities performed by the machine in the contextual situation;
responsive to determining the contextual situation of the machine has changed, program instructions to analyze one or more sensors associated with the machine and a first set of data generated by the one or more sensors associated with the machine;
program instructions to determine the one or more sensors associated with the machine are generating a required type of data and a required amount of data to create a subset of the digital twin model of the machine; and
program instructions to create the subset of the digital twin model of the machine incorporating the change detected.

9. The computer program product of claim 8, further comprising:
prior to monitoring the digital twin model of the machine for the one or more changes to the machine, program instructions to receive a request to create the digital twin model of the machine;
program instructions to gather a second set of data about the machine; and
program instructions to create the digital twin model of the machine.

10. The computer program product of claim 9, wherein gathering the second set of data about the machine further comprises:
program instructions to analyze the second set of data to evaluate an adaptability of the machine;
program instructions to analyze the second set of data to predict the contextual situation of the machine;
program instructions to analyze the second set of data to predict the one or more activities performed by the machine in the contextual situation;
program instructions to analyze the second set of data to predict a type of data generated by the one or more sensors associated with the machine; and
program instructions to analyze the second set of data to predict a volume of the type of data predicted to be generated by the one or more sensors associated with the machine.

11. The computer program product of claim 10, further comprising:
program instructions to store the second set of data about the machine in a knowledge corpus.

12. The computer program product of claim 8, wherein analyzing the one or more sensors associated with the machine and the first set of data generated by the one or more sensors associated with the machine further comprises:
program instructions to determine whether the type of data generated by the one or more sensors associated with the machine has changed; and
program instructions to determine whether a priority level of the type of data generated by the one or more sensors associated with the machine has changed.

13. The computer program product of claim 8, further comprising:
program instructions to determine the one or more sensors associated with the machine are not generating the required type of data to create the subset of the digital twin model of the machine based on the digital twin;
program instructions to recommend one or more additional sensors be installed in the contextual situation of the machine; and
program instructions to proactively install one or more additional sensors in the contextual situation of the machine.

14. The computer program product of claim 8, further comprising:
program instructions to determine the one or more sensors associated with the machine are not generating the required amount of data to create the subset of the digital twin model of the machine based on the digital twin; and
program instructions to enable an external scanning component to generate the required amount of data to create the subset of the digital twin model of the machine.

15. A computer system comprising:
one or more computer processors;
one or more computer readable storage media;
program instructions collectively stored on the one or more computer readable storage media for execution by at least one of the one or more computer processors, the stored program instructions comprising:
program instructions to monitors a digital twin model of a machine for one or more changes to the machine;
responsive to detecting a change to the machine, program instructions to analyzes one or more aspects of the machine, wherein the one or more aspects of the machine include a contextual situation of the machine and one or more activities performed by the machine in the contextual situation;
responsive to determining the contextual situation of the machine has changed, program instructions to analyzes one or more sensors associated with the machine and a first set of data generated by the one or more sensors associated with the machine;
program instructions to determines the one or more sensors associated with the machine are generating a required type of data and a required amount of data to create a subset of the digital twin model of the machine; and
program instructions to creates the subset of the digital twin model of the machine incorporating the change detected.

16. The computer system of claim 15, further comprising:
prior to monitoring the digital twin model of the machine for the one or more changes to the machine, program instructions to receive a request to create the digital twin model of the machine;
program instructions to gather a second set of data about the machine; and
program instructions to create the digital twin model of the machine.

17. The computer system of claim 16, wherein gathering the second set of data about the machine further comprises:
program instructions to analyze the second set of data to evaluate an adaptability of the machine;
program instructions to analyze the second set of data to predict the contextual situation of the machine;
program instructions to analyze the second set of data to predict the one or more activities performed by the machine in the contextual situation;
program instructions to analyze the second set of data to predict a type of data generated by the one or more sensors associated with the machine; and
program instructions to analyze the second set of data to predict a volume of the type of data predicted to be generated by the one or more sensors associated with the machine.

18. The computer system of claim 15, wherein analyzing the one or more sensors associated with the machine and the first set of data generated by the one or more sensors associated with the machine further comprises:
program instructions to determine whether the type of data generated by the one or more sensors associated with the machine has changed; and
program instructions to determine whether a priority level of the type of data generated by the one or more sensors associated with the machine has changed.

19. The computer system of claim 15, further comprising:
program instructions to determine the one or more sensors associated with the machine are not generating the required type of data to create the subset of the digital twin model of the machine based on the digital twin;
program instructions to recommend one or more additional sensors be installed in the contextual situation of the machine; and
program instructions to proactively install one or more additional sensors in the contextual situation of the machine.

20. The computer system of claim 15, further comprising:
program instructions to determine the one or more sensors associated with the machine are not generating the required amount of data to create the subset of the digital twin model of the machine based on the digital twin; and
program instructions to enable an external scanning component to generate the required amount of data to create the subset of the digital twin model of the machine.
